(19) United States
(12) Patent Application Publication
(10) Pub. No.: US 2010/0164929 A1
(43) Pub. Date: Jul. 1, 2010

(54) SOURCE DRIVER

(75) Inventors: Yi Cheng Chen, Tainan County (TW); Yann Hsiung Liang, Hsinchu City (TW); Chin Chieh Chao, Hsinchu City (TW); Hui Wen Miao, Hsinchu City (TW); Ko Yang Tso, Zhonghe City (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: RAYDIUM SEMICONDUCTOR CORPORATION, Hsinchu (TW)

(21) Appl. No.: 12/578,883

(22) Filed: Oct. 14, 2009

(30) Foreign Application Priority Data
Oct. 15, 2008 (TW) 097139554

(51) Int. Cl. G09G 3/36; G06F 3/038; H03B 1/00

(52) U.S. Cl. 345/211; 327/108; 345/98

(57) ABSTRACT

The invention discloses a source driver. The source driver comprises a plurality of channels and a control module. Each of the plurality of channels comprises an output buffer, an output pad, a driving switch, and a charge sharing switch. The control module is used to control a gate signal of the driving switch or the charge sharing switch in each channel to be changed linearly. By doing so, a peak current generated by the source driver can be lowered to reduce the electromagnetic interference (EMI).

### BACKGROUND OF THE INVENTION

1. Field of the invention

The present invention relates to a liquid crystal display (LCD), and more particularly, the invention relates to a source driver applied to a thin film transistor liquid crystal display (TFT-LCD).

2. Description of the prior art

Recently, there are various types of display apparatus, for example, the liquid crystal display, the plasma display, shown on the market with the developing technology. Because the liquid crystal display has smaller size than a conventional CRT monitor, thus, the liquid crystal display is more convenient than the CRT monitor for modern people living in a small space.

As to a general thin film transistor liquid crystal display, its driving apparatus comprises a source driver (or a date driver) and a gate driver (or a scan driver). Please refer to FIG. 1. FIG. 1 illustrates an equivalent circuit of a TFT-LCD panel in prior art.

As shown in FIG. 1, a sub-pixel of a TFT-LCD is composed of thin film transistors TFT, a liquid crystal, and a capacitor Cs. The thin film transistor TFT is used as a switch and the gate driver scans each of the scan lines in order, so as to turn on the scan lines from top to bottom. When thin film transistors in one row are turned on, the source driver is used to write the information voltage. As to the capacitor Cs and the liquid crystal are connected in parallel to increase the capacitance to maintain the information voltage.

It should be noticed that the function of the source driver is to transmit analog signals to a LCD panel after high speed digital signals are received and converted into the analog signals and level shifted. The converting speed should be fast enough otherwise the switching speed of images will be affected. Because the LCD panel itself is a very huge load, the output level must have powerful driving capacity to charge (or discharge) each pixel of the LCD panel has to the desired voltage level in short time. Therefore the source driver plays a very important role for a TFT-LCD which is emphasized on high quality, high resolution and low power consumption.

Please refer to FIG. 2. FIG. 2 illustrates an output circuit of a source driver in prior art. As shown in FIG. 2, the output circuit 2 comprises n channels from a first channel 21 to nth channel 2n. The first channel 21 corresponds to the first data line Y1 of the TFT-LCD panel; the second channel corresponds to the second data line Y2; the nth channel 2n corresponds to the nth information line Yth; and so on. Taking the first channel 21 for example, before a voltage driven by the output buffer 211 is applied across the output pad 212, the voltage is applied across a driving switch 213 (controlled by Vs) and a charge sharing switch 214 (controlled by Vc).

Because the strobe input signal from an output buffer will generate a pulse on each of the lines. During the pulse period, the driving switch will be turned off to separate the output buffer and the output pad and the charge sharing switch will be turned on to share charges. When the pulse period ends, the charge sharing switch will be turned off to finish the charge sharing and the driving switch is turned on to drive a voltage to the output pad.

That is to say, the source driver will share charges during a rising edge of the pulse and a first instantaneous current will be generated; the source driver will finish the charge sharing during a falling edge of the pulse and the output buffer will start to drive a voltage to the output pad, so a second instantaneous current will be generated. Therefore, the conventional source driver has serious electromagnetic interference (EMI) problem caused by large first instantaneous current and second instantaneous current, and even the normal operation of TFT-LCD will be affected.

In order to reduce the electromagnetic interference of the conventional source driver, a high-voltage logic buffer is used to control the rising/falling time of the gate signals of the driving switch and the charge sharing switch. The circuit structure is shown in FIG. 3.

However, in this driving method, the gate signals of the driving switch and the charge sharing switch do not change linearly. The gate signals change slowly in the regions around the rising/falling edge, but the gate signals change fast in the middle region between the rising edge and the falling edge. Thus, the equivalent resistances of the driving switch and the charge sharing switch change fast and large instantaneous currents will be generated, as shown in FIG. 4(A) and FIG. 4(B).

Moreover, even the driving capacity of the logic buffer is lowered in order to increase the rising/falling time of the gate signals of the driving switch and the charge sharing switch. As shown in FIG. 4(C), the gate signals change more slowly in the regions around the rising/falling edge, but the gate signals still change fast in the middle region between the rising edge and the falling edge. Therefore, although the instantaneous currents become lower, the electromagnetic interference effect can not be effectively prevented.

Therefore, the invention provides a source driver to solve the aforementioned problems.

### SUMMARY OF THE INVENTION

The invention is to provide a source driver. When the source driver is used for driving a TFT-LED panel, the source driver can effectively reduce an instantaneous current and lower the electromagnetic interference caused by an instantaneous current. Thereby the TFT-LCD can operate normally.

One preferred embodiment of the invention is a source driver. In the embodiment, the source driver comprises a plurality of channels coupled to the TFT-LCD panel and a control module. Each of the plurality of channels corresponds to a data line on the TFT-LCD panel respectively. Each channel comprises an output buffer, an output pad, a driving switch, and a charge sharing switch. In each channel, a voltage signal driven by the output buffer will be transmitted through the driving switch and the charge sharing switch and then to the output pad. The control module is used to control the gate signals of the driving switch and the charge sharing switch in each channel to rise or fall linearly. Thus, the instantaneous current can be reduced, so as to lower the electromagnetic interference effect.

In practical applications, the control module can comprise a high voltage logic buffer. The feature of the high voltage logic buffer circuit structure is to set a capacitor between a specific contact and the output terminal and to control the charging/discharging current to the specific contact through a stationary current, so as to control the rising/falling waveform of the output terminal is linear. In fact, the slope of the linear rising/falling waveform relates to the stationary current source and the capacitance.

Compared with the prior art, the source driver of the invention adjusts the gate signals of the driving switch and the charge sharing switch to be linear by a way of linear adjustment. Therefore, the instantaneous current can be reduced and the electromagnetic interference resulted from the instantaneous current can be also lowered effectively.

In addition, the source driver can change the slew rate of the rising/falling edge and the rising/falling time of the gate signals by adjusting the stationary current and the capacitance. And, since the load of the TFT-LCD panel is not directly related, the rising/falling time will not be affected by the magnitude of the load.

The objective of the present invention will no doubt become obvious to those of ordinary skill in the art after reading the following detailed description of the preferred embodiment, which is illustrated in the various figures and drawings.

### BRIEF DESCRIPTION OF THE APPENDED DRAWINGS

FIG. 1 illustrates an equivalent circuit of a TFT-LCD panel in prior art.

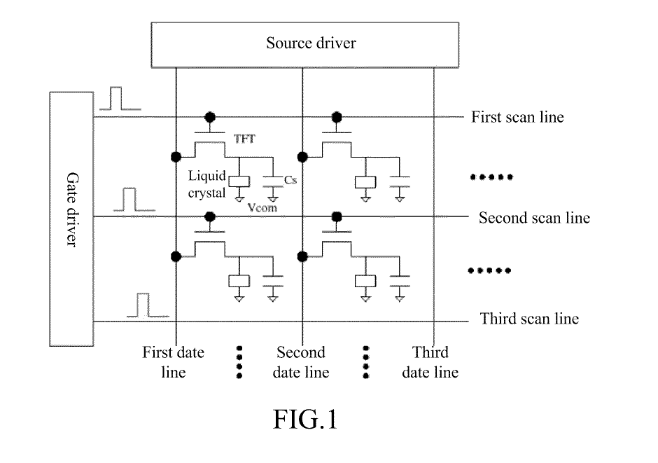

FIG. 2 illustrates an output circuit of a source driver in prior art.

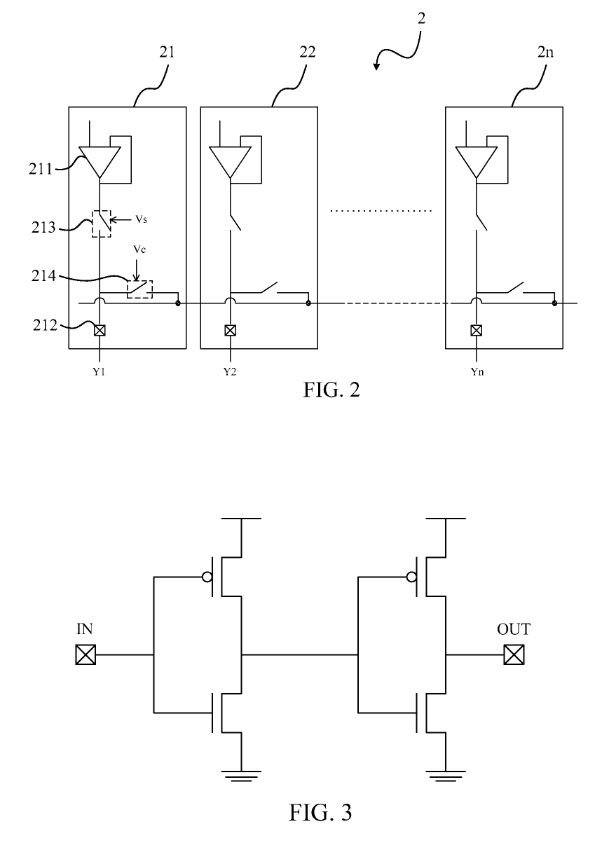

FIG. 3 illustrates a high voltage logic buffer circuit structure in prior art.

FIG. 4(A) and FIG. 4(B) illustrate the effects of the high voltage logic buffer in FIG. 3 on the waveform of the gate signals of the driving switch and the charge sharing switch respectively.

FIG. 4(C) compares the effects of the first high voltage logic buffer with stronger driving capacity with the effects of the second high voltage logic buffer with weaker driving capacity on the waveform of the gate signals of the driving switch.

FIG. 5 illustrates an output circuit of a source driver according to an embodiment of the present invention.

FIG. 6 illustrates a high voltage logic buffer circuit structure of the present invention.

FIG. 7(A) and FIG. 7(B) illustrate the effects of the high voltage logic buffer in FIG. 6 on the rising waveform of the gate signals of the driving switch and the charge sharing switch respectively.

FIG. 8 compares the effects of the high voltage logic buffer in FIG. 6 with the conventional high voltage logic buffer in FIG. 3 on the rising waveform of the gate signals of the driving switch.

FIG. 9 compares the effects of the high voltage logic buffer in FIG. 6 and the conventional high voltage logic buffer in FIG. 3 on the rising waveform of the gate signals of the charge sharing switch.

FIG. 10 illustrates another high voltage logic buffer circuit structure of the present invention.

FIG. 11(A) and FIG. 11(B) illustrate the effects of the high voltage logic buffer in FIG. 10 on the falling waveform of the gate signals of the driving switch and the charge sharing switch respectively.

FIG. 12 compares the effects of the high voltage logic buffer in FIG. 10 with a conventional high voltage logic buffer on the falling waveform of the gate signals of the driving switch.

FIG. 13 compares the effects of the high voltage logic buffer in FIG. 10 with a conventional high voltage logic buffer on the falling waveform of the gate signals of the charge sharing switch.

### DETAILED DESCRIPTION OF THE INVENTION

The invention provides a source driver for a TFT-LCD panel. When the source driver drives the TFT-LCD panel, it can reduce the instantaneous currents effectively and lowers electromagnetic interference effect resulted from the instantaneous currents. Thereby the TFT-LCD can operate normally.

The following description will describe the theory and concept of the source driver of the invention. In general, the performance of a source driver depends on the driving capacity of its output buffer, the equivalent resistance of a driving switch and a charge sharing switch, and a RC load of a panel. If the driving capacity of the output buffer and the RC load of the panel are fixed, the performance of the source drive is affected by the equivalent resistance of the driving switch and the charge sharing switch.

For example, when the driving switch has smaller equivalent resistance, the output buffer can charge the RC load of the panel to a target voltage value with a larger current in a shorter output delay time. However, smaller equivalent resistance of the driving switch will cause larger instantaneous current and more serious electromagnetic interference effect. Similarly, smaller equivalent resistance of the charge sharing switch will cause larger current for sharing charge and improves the performance of charge sharing. By doing so, more electricity can be saved and the temperature of IC is lowered, but the larger instantaneous current and the serious electromagnetic interference effect will be also caused.

In general, a driving switch or a charge sharing switch is realized by the metal oxide semiconductor field effect transistors, such as CMOS or N/PMOS. The equivalent resistance of the switch relates to the width to length ratio (W/L) of the transistor and the rising/falling time of the gate signals. For example, if a switch has a transistor with higher r width to length ratio, the switch has lower equivalent resistance, so that the larger instantaneous current and serious electromagnetic interference effect will be generated. On the contrary, if a switch has a transistor with smaller width to length ratio, the switch has higher equivalent resistance, so that the larger instantaneous current will become smaller and the electromagnetic interference effect will be reduced.

Additionally, while the gate signals do not rise to a high level or fall to a low level completely, the equivalent resistance of a switch will change with the variation of the gate signals. If the rising/falling time of the gate signals of a switch is longer, the equivalent resistance of the switch will change slowly and the electromagnetic interference will not be obvious. On the contrary, if the rising/falling time of the gate signals of a switch is shorter, the equivalent resistance of the switch will change fast, so as to produce larger instantaneous current resulted in serious electromagnetic interference effect.

In practical applications, due to the specification limitations of output delay time and IC temperature, the width to length ratio of the transistor in the driving switch and the charge sharing switch can only be adjusted in a confined range. Therefore, the only possible way is to reduce the electromagnetic interference effect by controlling the rising/falling time of the gate signals of the switch.

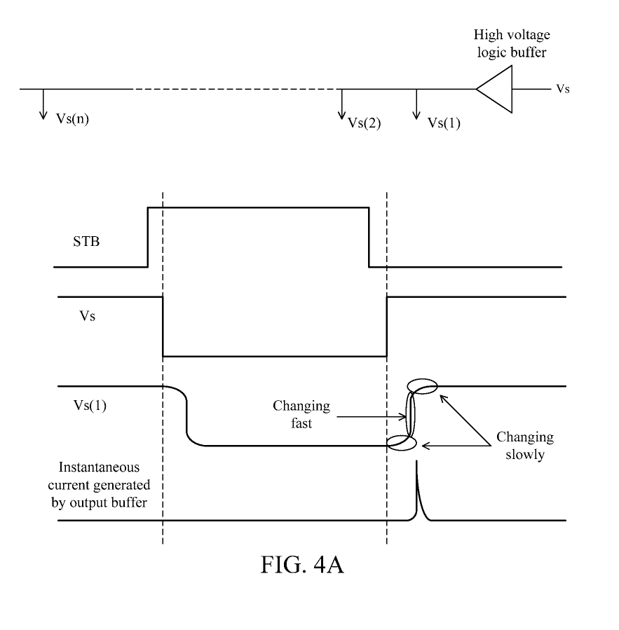

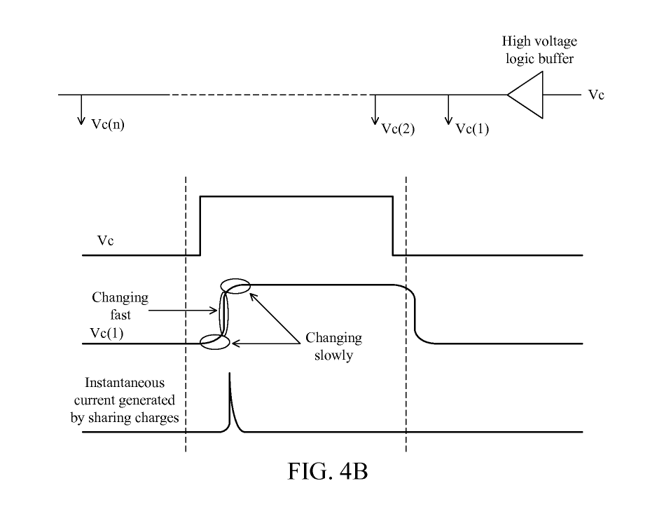

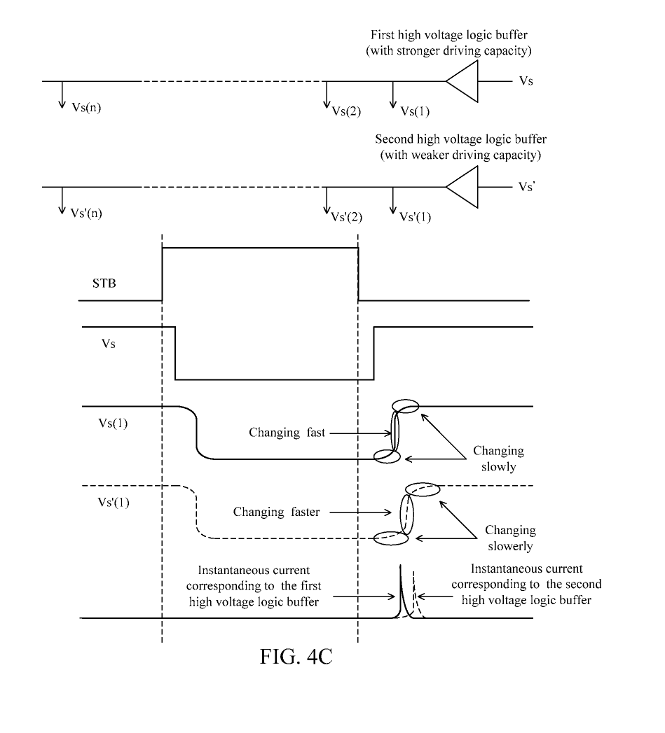

However, under a driving method of the conventional high voltage logic buffer (shown in FIG. 3), gate signals of the driving switch and the charge sharing switch do not change linearly. The gate signals change slowly in the prior and behind regions of the rising/falling edge, but they change fast in the middle region between the rising edge and the falling edge. Thus, the equivalent resistances of the driving switch and the charge sharing switch change fast and large instantaneous current will be generated, as shown in FIG. 4(A) and FIG. 4(B). Even the driving capacity of the logic buffer is lowered (the second high voltage logic buffer with weaker driving capacity takes place the first high voltage logic buffer with high driving capacity) in order to increase the rising/falling time of the gate signals. It results in the gate signals changing more slowly in the prior and behind region of the rising/falling edge, but the gate signals still change fast in the middle region between the rising edge and the falling edge. The electromagnetic interference cannot be prevented effectively, as shown in FIG. 4(C).

The present invention is to provide a new source driver for reducing the electromagnetic interference. The new source driver has a new logic buffer circuit which controls the gate signals of the driving switch and the charge sharing switch to rise or fall linearly. By doing so, the instantaneous currents can be lowered, so as to reduce the electromagnetic interference effect.

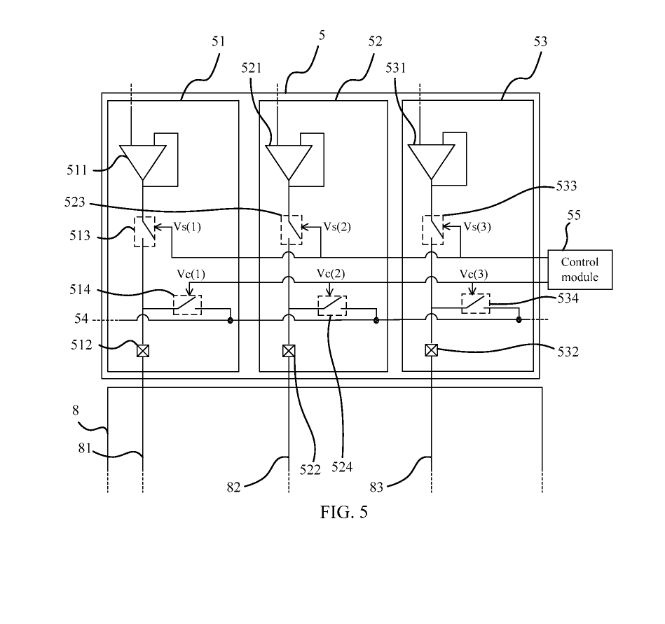

An embodiment of the present invention is a source driver. Please refer to FIG. 5. FIG. 5 illustrates an output circuit of the source driver. As shown in FIG. 5, the source driver 5 comprises a first channel 51, a second channel 52, and a third channel 53 coupled to a channel of a TFT-LCD panel 8, a common wire 54, and a control module 55, wherein the first channel 51, the second channel 52, and the third channel 53 correspond to the first date line 81, the second date line 82, and the third date line 83 on the TFT-LCD panel 8 respectively.

In fact, the number of the channels of the driving source 5 relates to the number of the date lines on the TFT-LCD panel 8, but not limited by this case. Other parts of the driving source 5 are conventional art and not claimed in the present invention.

In this embodiment, the first channel 51 comprises a first output buffer 511, a first output pad 512, a first driving switch 513, and a first charge sharing switch 514; the second channel 52 comprises a second output buffer 521, a second output pad 522, a second driving switch 523, and a second charge sharing switch 524; the third channel 53 comprises a third output buffer 531, a third output pad 532, a third driving switch 533, and a third charge sharing switch 534. The first charge sharing switch 514, a second charge sharing switch 524, and a third charge sharing switch 534 are all coupled to the common wire 54.

It should be noticed that the first driving switch 513, the second driving switch 523, and the third driving switch 533 are coupled to the control module 55 respectively and controlled by the control voltages Vs(1), Vs(2), and Vs(3). The control module 55 supplies the control voltages Vs(1), Vs(2), and Vs(3) for controlling the gate signals of the first driving switch 513, the second driving switch 523, and the third driving switch 533 to be change linearly. The first charge sharing switch 514, the second charge sharing 524, and the third charge sharing 534 are coupled to the control module 55 respectively and controlled by the control voltages Vc(1), Vc(2), and Vc(3) which are also supplied by the control module 55.

In this embodiment, before the voltage signal driven by the output buffer of each channel is transmitted to the output pad of the channel, the voltage signal passes through the driving switch and charge sharing switch of the channel firstly. Taking the first channel 51 for example, the first voltage signal driven by the first output buffer 511 will pass through the first driving switch 513 and the first charge switch 514, and then the first voltage signal is transmitted to the first output pad 51.

When the first strobe input signal from the first output buffer 511 generates a pulse, the first driving switch 513 is turned off to separate the output buffer 511 from the first output pad 512, and the first charge sharing switch 514 will be turned on to share charges during the pulse period. Therefore, the first output buffer 511 can not drive the voltage signal to the first output pad 512 during the pulse period, the first output buffer 511 performs the charge sharing procedure to save the electricity and lower the IC temperature.

When the pulse period ends, the first charge sharing switch 514 will be turned off to terminate the charge sharing procedure. At the same time, the first driving switch 513 will be turned on and thereby the first output buffer 511 can drive the voltage signal to the first data line 81 via the first output pad 512.

Similarly, in the second channel 52, before the second voltage signal driven by the second output buffer 512 is transmitted to the second output pad 522, the second voltage signal passes through the second driving switch 523 and the second charge sharing switch 524. Within the pulse period of the second strobe input signal output from the second output buffer 521, the second driving switch 523 will be turned off to separate the second output buffer 521 from the second output pad 522. The second charge sharing 524 will be turned on to share charge at the same time. When the pulse period ends, the second charge sharing switch 524 will be turned off to terminate the charge sharing procedure and the second driving switch 523 will be turned on to drive the voltage signal to the second output pad 522 and the second data line 82. The condition of the third channel 53 is the same as above and it does not be explained again.

Taking the first channel 51 for example, the source driver 5 will share charges during the rising edge of the pulse and the first instantaneous current will be generated; and the source driver 5 will stop the charge sharing during the falling edge of the pulse and the second instantaneous current will be also generated.

However, the source device of the invention is different from the conventional one which companies with serious electromagnetic interference effect resulted from larger first instantaneous current and second instantaneous current and the TFT-LCD can not operate normally. The invention provides a new high voltage logic buffer circuit for the control module 55. The control voltage which is produced by the circuit structure controls the gate signals of each driving switch and each charge switch to be change linearly, so as to lower the instantaneous currents and the electromagnetic interference effect. Subsequently, the high voltage logic buffer circuit structure of the present invention will be introduced as follows.

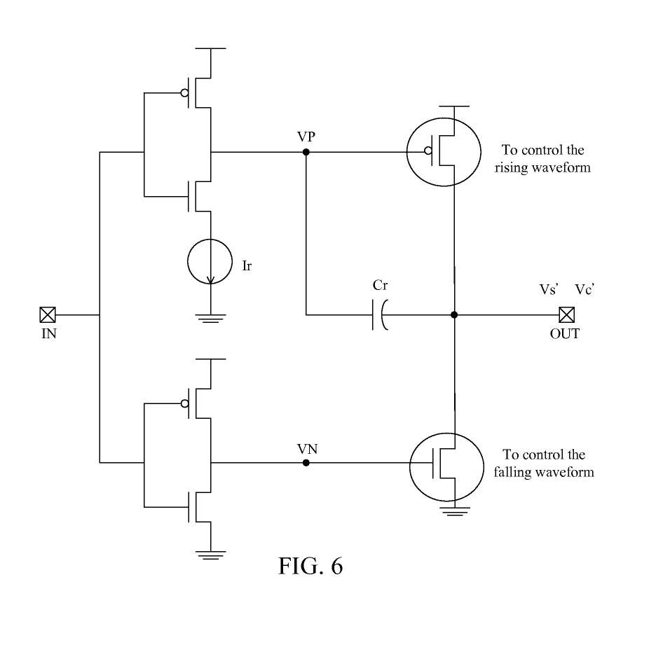

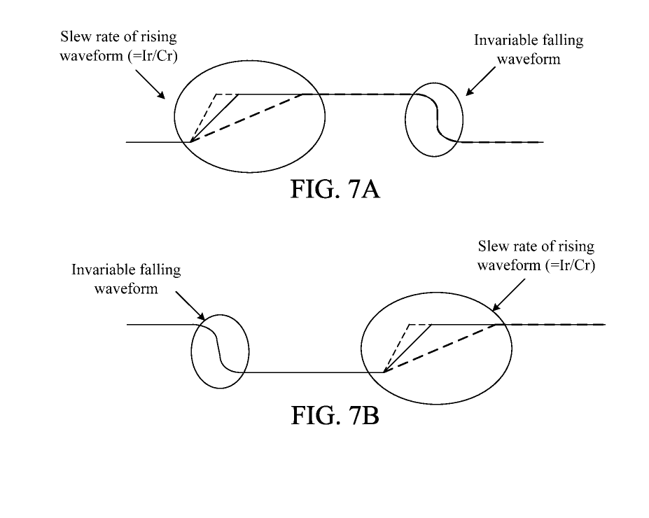

Please refer to FIG. 6. FIG. 6 illustrates a circuit structure of a high voltage logic buffer. When the driving switch and the charge sharing switch are all realized by NMOS, the circuit structure is used to control the rising waveforms of gate signals of the driving switch and the charge sharing switch to be raised linearly, as shown in FIG. 7(A) and FIG. 7(B) respectively. It should be noticed that the circuit structure will not change the falling waveforms of the gate signals of the driving switch and the charge sharing switch to be linear.

In this circuit structure, because a capacitor Cr is set between a contact VP and an output terminal OUT and the discharge current of the contact VP is controlled by the stationary current Ir, the rising waveform of the output terminal OUT can be linear. The rising slope is related to the stationary current Ir and the capacitance Cr. For example, the larger stationary current Ir is or the smaller capacitance Cr is, the larger rising slope (absolute value) is; the smaller stationary current Ir is or the larger capacitance Cr is, the smaller rising slope (absolute value) is.

Additionally, a user can adjust the slew rate of the linear rising waveform according to the practical requirement via the circuit structure. For example, if the major considered factor is to reduce electromagnetic interference effect, the slew rate of linear rising waveform is as low as better. In other words, the linear rising waveform is as flatten as possible and it can be realized by lowering the stationary current Ir or increase the capacitance Cr. However, if the major considered factor is to reduce the output delay time, then the slew rate of linear rising waveform is as high as better. In other words, the linear rising waveform is as sharp as possible and it can be realized by increasing the stationary current Ir or lowering the capacitance Cr.

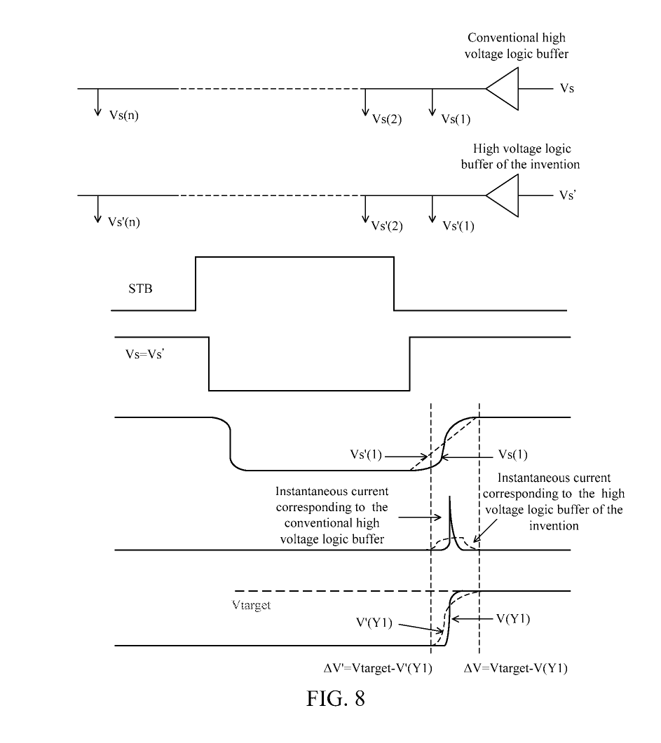

Please refer to FIG. 8. FIG. 8 compares the effects of the high voltage logic buffer in FIG. 6 with the conventional high voltage logic buffer in FIG. 3 on the rising waveform of the gate signals of the driving switch. As shown in FIG. 8, the rising waveform of the high voltage logic buffer of the invention rises linearly and thus the generated instantaneous current is smaller than the conventional high voltage buffer. Additionally, during the process of reaching target voltage value, the curve V′(Y1) of the high voltage logic buffer in the invention is flatter than the curve V(Y1) of the conventional high voltage logic buffer. The situation that the gate signals change slowly in the prior/behind region and change fast in the middle region will not occur often.

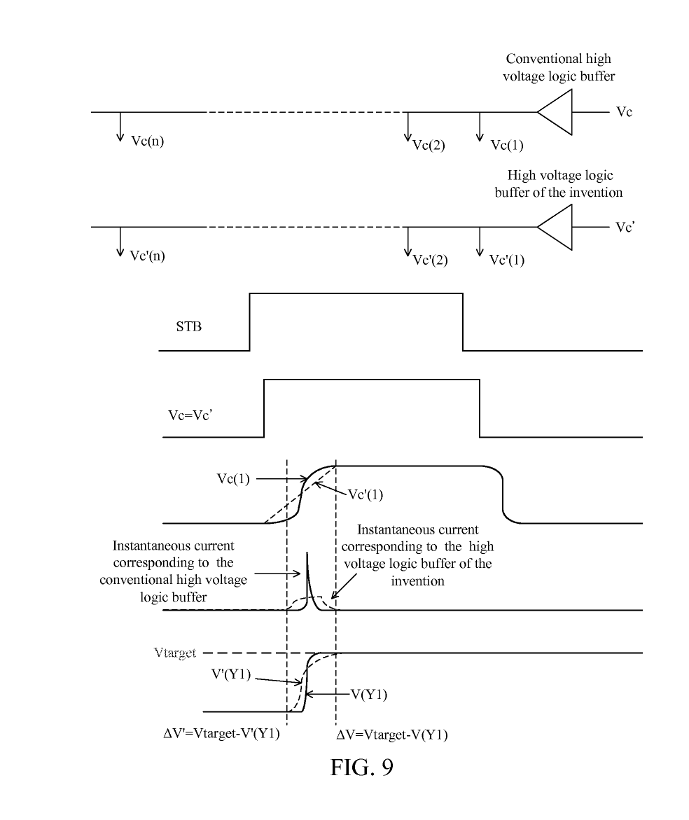

Please refer to FIG. 9. FIG. 9 compares the effects of the high voltage logic buffer in FIG. 6 and the conventional high voltage logic buffer in FIG. 3 on the rising waveform of the gate signals of the charge sharing switch. As shown in FIG. 9, the rising waveform of the high voltage logic buffer of the invention rises linearly and thus the instantaneous current is smaller than the conventional high voltage buffer. Additionally, during the process of reaching target voltage value, the curve V′(Y1) of the high voltage logic buffer in the invention is flatter than the curve V(Y1) of the conventional high voltage logic buffer. The situation that the gate signals change slowly in the prior/behind region and change fast in the middle region will not occur often.

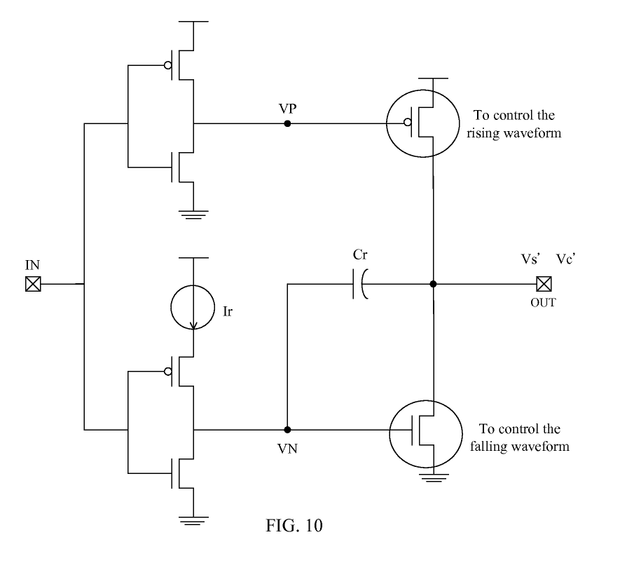

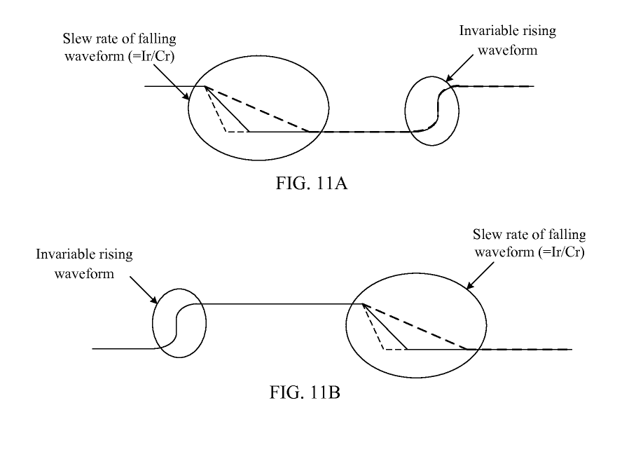

Please refer to FIG. 10. FIG. 10 illustrates a circuit structure of another high voltage logic buffer of the present invention. When the driving switch and the charge sharing switch are both realized by PMOS, the circuit structure can control the falling waveform of the gate signal of the driving switch and the charge sharing switch to fall linearly, as shown in FIG. 11(A) and FIG. 11(B). It should be noticed that the circuit structure can not control the rising waveform of the gate signal of the driving switch and the charge sharing switch to rise linearly.

In the circuit structure, because a capacitor Cr is set between a contact VP and an output terminal OUT and the discharge current of the contact VN is controlled by the stationary current Ir, the falling waveform of the output terminal OUT can be linear. The falling slope relates to the stationary current Ir and the capacitance. For example, the larger the stationary current Ir is or the smaller the capacitance Cr is, the larger falling slope (absolute value) is; the smaller the stationary current Ir is or the larger the capacitance Cr is, the smaller the falling slope (absolute value) is.

Additionally, the user can adjust the slew rate of the linear falling waveform according to the practical requirement through the circuit structure. For example, if the major considered factor is to reduce the electromagnetic interference effect, the linear falling waveform which is as flatten as better can be realized by lowering the stationary current Ir or increase the capacitance Cr. However, if the major considered factor is to enhance the output efficiency, then the linear falling waveform is as sharp as better which can be realized by increasing the stationary current Ir or lowering the capacitance Cr.

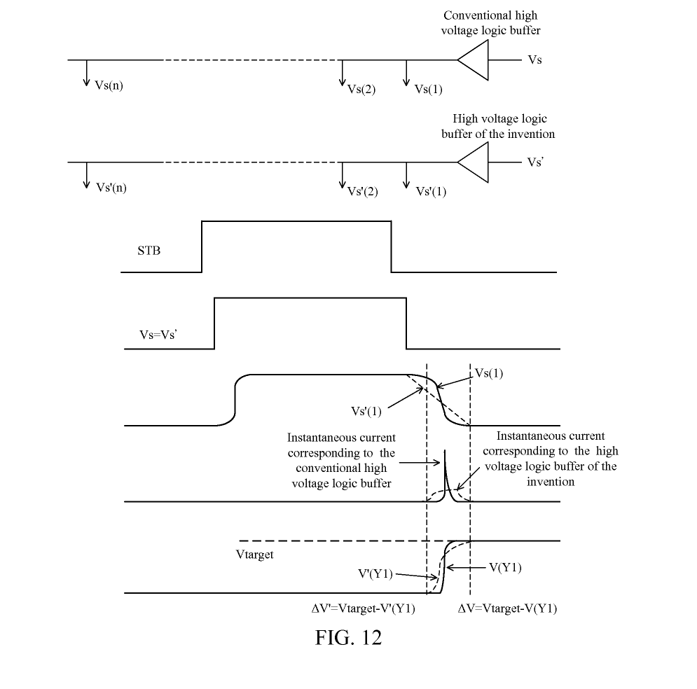

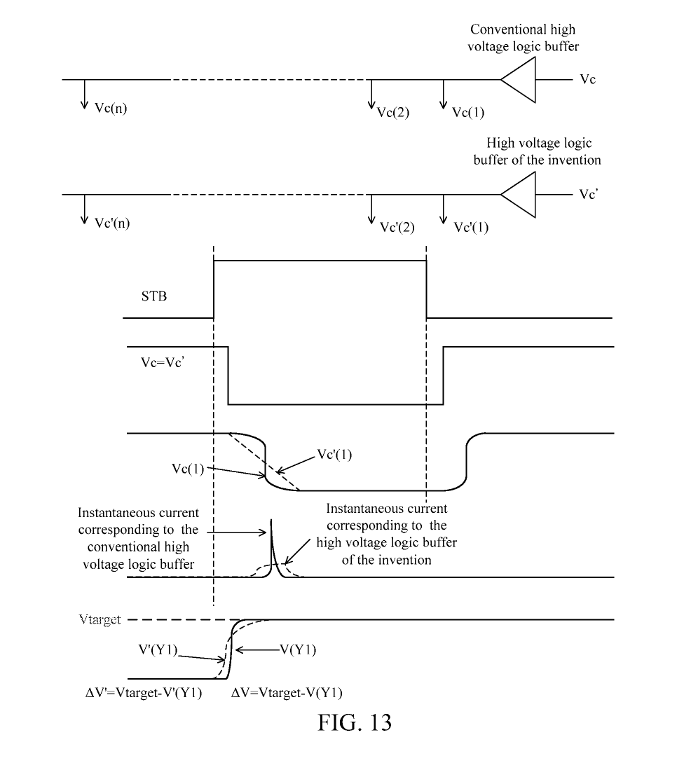

Please refer to FIG. 12. FIG. 12 compares the effects of the high voltage logic buffer in FIG. 10 with a conventional high voltage logic buffer on the falling waveform of the gate signals of the driving switch. As shown in FIG. 12, because the high voltage logic buffer of the invention can control the falling waveform of the gate signals of the driving switch to be linear, thus the instantaneous current of the high voltage logic buffer is smaller than the instantaneous current of the conventional high voltage buffer. Additionally, the curve V′(Y1) of the high voltage logic buffer in the invention is flatter than the curve V(Y1) of the conventional high voltage logic buffer during the process of reaching target voltage value. The situation that the gate signals change slowly in the prior/behind region and change fast in the middle region will not occur often. Please refer to FIG. 13. FIG. 13 compares the effects of the high voltage logic buffer in FIG. 10 with a conventional high voltage logic buffer on the falling waveform of the gate signals of the charge sharing switch. As shown in FIG. 13, because the high voltage logic buffer of the invention can control the falling waveform of the gate signals of the charge sharing switch to be linear, thus the instantaneous current of the high voltage logic buffer of the invention is smaller than the instantaneous current of the conventional high voltage buffer. Additionally, the curve V′(Y1) of the high voltage logic buffer is flatter than the curve V(Y1) of the conventional high voltage logic buffer during the process of reaching target voltage value. The situation that the gate signals change slowly in the prior/behind region and change fast in the middle region will not occur often.

To sum up, compared with the prior art, a source driver of the invention adjusts the gate signals of a driving switch and a charge sharing switch to be linear by a way of linear adjustment and thus the rising/falling edge of the gate signals can be changed linearly. Therefore the instantaneous current can be reduced so as to lower electromagnetic interference effect resulted from the instantaneous current.

Additionally, because the source driver can change the slew rate on the rising/falling edge of the gate signals by adjusting the stationary current and the capacitance, it can also adjust the rising/falling time of the gate signals. The slew rate and the rising/falling time do not relate to the load of the TFT-LCD panel directly and are not affected by the magnitude of the load.

Although the present invention has been illustrated and described with reference to the preferred embodiment thereof, it should be understood that it is in no way limited to the details of such embodiment but is capable of numerous modifications within the scope of the appended claims.

What is claimed is:

1. A source driver, comprising:
plurality of channels, one of the plurality of channels comprises:
output pad;
output butter for driving a voltage signal; and
first switch coupled between the output puffer and output pad, when the first switch is turned on, the voltage signal being transmitted to the output pad through the first switch; and
control module, coupled to the first switch, for controlling a first gate signal of the first switch to be changed linearly.

2. The source driver of claim 1, wherein the control module comprises a plurality of transistors and a first capacitance, a first slew rate of the rising/falling edge of the first gate signal waveform is related to the first capacitance and a first stationary current of the control module.

3. The source driver of claim 1, wherein the first switch is realized by using a metal oxide semiconductor field-effect transistor (MOSFET).

4. The source driver of claim 1, wherein the channel further comprises:
second switch coupled to a contact and a common wire between the first switch and the output pad, when the first switch is turned on, the second switch is simultaneously turned on to share charges.

5. The source driver of claim 4, wherein the second switch is realized by using a metal oxide semiconductor field-effect transistor (MOSFET).

6. The source driver of claim 4, wherein the control module is coupled to the second switch, the control module also controls a second gate signal of the second switch to be changed linearly.

7. The source driver of claim 6, wherein the control module comprises a plurality of transistors and a second capacitor, a second slew rate of the rising/falling edge of the second gate signal waveform is related to the second capacitor and a second stationary current of the control module.

8. The source driver of claim 1, wherein the channel is coupled to one of a plurality of data lines on a panel through the output pad and transmits the voltage signal to the data line.

9. The source driver of claim 8, wherein the panel is a thin-film transistor liquid crystal display (TFT-LCD) panel.
